(19) United States
(12) Patent Application Publication
(10) Pub. No.: US 2013/0115779 A1
(43) Pub. Date: May 9, 2013

(54) Conical Sleeves For Reactors

(71) Applicant: Intermolecular, Inc., San Jose, CA (US)

(72) Inventors: Gregory P. Lim, Fremont, CA (US); Jeffrey Chih-Hou Lowe, Cupertino, CA (US); Sandeep Mariserla, Danbury, CT (US); Robert Anthony Sculac, Lake Oswego, OR (US)

(73) Assignee: INTERMOLECULAR, INC., San Jose, CA (US)

(21) Appl. No.: 13/662,078

(22) Filed: Oct. 26, 2012

Related U.S. Application Data
(60) Provisional application No. 61/557,546, filed on Nov. 9, 2011.

(51) Int. Cl. H01L 21/306; H01L 21/308

(52) U.S. Cl. 438/706; 438/745; 156/345.3; 156/345.19; 257/E21.219

(57) ABSTRACT

In some embodiments, the present invention discloses sealing mechanisms for generating site isolated regions on a substrate, allowing combinatorial processing without cross contamination between regions. The sealing mechanism can include a thin sharp edge ring for pressing on the substrate surface with small contact area. The small sealing area can concentrate the sealing force, generating higher contact pressure to guard against fluid leakage across the sealing surface, for example, eliminating fluid wicking at the seal interface through capillary action. The sealing mechanism can include multiple protrusions, which contacts the substrate leaving a small gap at the remaining portion of the sealing mechanism. The sealing mechanism can include minimal contact points with the substrate, which can significantly reduce the particle generation during processing. A pressure differential can be established across the sealing surface to prevent fluid leakage.

The present invention claims priority to U.S. provisional patent application Ser. No. 61/557,546, filed Nov. 9, 2011, entitled “Conical Sleeve for Reactors”, hereby incorporated by reference for all purposes.

### TECHNICAL FIELD

The present invention relates generally to combinatorial methods for device process development.

### BACKGROUND OF THE INVENTION

The manufacture of integrated circuits and other substrate-based components entails the integration and sequencing of many unit processing steps. As an example, IC manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

Currently, good sealing on a surface coated with soft, deformable or sticky materials, such as a photoresist, can be difficult, for example, due to the tendency of the wet chemistry being tested to wick under the sealing surface through capillary action. In addition, the wicking action can generate partial reaction areas in the vicinity of the sealing surface. Thus there is a need for improve sealing in site isolated regions in HPC systems.

### SUMMARY OF THE DESCRIPTION

In some embodiments, the present invention discloses systems and methods for generating site isolated regions on a substrate, allowing combinatorial processing without cross contamination between regions. The site isolated regions are sealed against each other through a sealing mechanism that can be effective for different substrate surface conditions, including surface layer removal at the sealing interface.

In some embodiments, the sealing mechanism includes a thin sharp edge ring for pressing on the substrate surface with small contact area. For example, the sealing mechanism can include a conical seal having taper edges toward the substrate surface. The small sealing area can concentrate the sealing force, generating higher contact pressure to guard against fluid leakage across the sealing surface, for example, eliminating fluid wicking at the seal interface through capillary action.

In some embodiments, the conical seal can form a better seal with a deformable substrate layer, such as a photoresist layer, by heating the deformable layer before forming the seal contact. When cooling, the conical seal can be partially embedded in the deformable layer, improving the sealing characteristics (apply as a separate patent?).

In some embodiments, the sealing mechanism includes multiple protrusions, which contact the substrate leaving a small gap at the remaining portion of the sealing mechanism. The sealing mechanism can include minimal contact points with the substrate, which can significantly reduce the particle generation during processing. A pressure differential can be established across the sealing surface to prevent fluid leakage.

In some embodiments, the present conical seal can be used in a high productivity combinatorial (HPC) system. During normal operation of an HPC system, a reactor module comprising a plurality of reactors can create a plurality of isolated regions on a substrate surface. The isolated regions are processed with process conditions, device structure or materials varying in a combinatorial manner. In an exemplary configuration, a reactor comprises a conical seal, pressing on a region of the substrate surface to create an isolated processing region. The conical seal can improve the pressing contact characteristics, forming better seal due to the conical sharp edges, reducing fluid leakage due to higher contact pressure and reducing particles due to smaller contact area.

In some embodiments, the present invention discloses methods to operate an HPC system comprising reactors having conical seal. Photoresist stripping, layer etching, and depositing can be effectively confined to the site isolated regions with the conical seal.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration that includes site isolated processing and/or conventional processing in accordance with one embodiment of the invention.

FIG. 3 illustrates a schematic diagram of a substrate that has been processed in a combinatorial manner.

FIG. 4 illustrates a schematic diagram of a combinatorial wet processing system according to an embodiment described herein.

FIG. 5 illustrates an exemplary high productivity combinatorial system, which employs reactor assemblies for creating site isolated regions on a substrate according to some embodiments of the present invention.

FIGS. 6A-6B show a cross section and a perspective view of a conical sealing system according to some embodiments of the present invention.

FIG. 7A illustrates an exemplary reactor having a conical seal according to some embodiments of the present invention.

FIG. 7B illustrates an exemplary configuration of forming a site isolated region according to some embodiments of the present invention.

FIGS. 8A-8E illustrate an exemplary process flow for processing a photoresist layer according to some embodiments of the present invention.

FIGS. 9A-9D illustrate a process flow for processing a layer according to some embodiments of the present invention.

FIG. 10 illustrates a flowchart for forming a site isolated region according to some embodiments of the present invention.

FIG. 11 illustrates a flowchart for processing a photoresist layer according to some embodiments of the present invention.

FIG. 12 illustrates a flowchart for processing a layer according to some embodiments of the present invention.

FIGS. 13A-13B illustrate an example of a reactor having contact points according to some embodiments of the current invention.

FIGS. 14A-14B illustrate an example of an outside surface processing according to some embodiments of the present invention.

FIG. 15 illustrates a flowchart for forming a site isolated region according to some embodiments of the present invention.

FIG. 16 illustrates another flowchart for forming a site isolated region according to some embodiments of the present invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

In some embodiments, the current invention relates to systems and methods for sealing site-isolated for use in the development of processes for the manufacture of integrated circuits (IC). The systems and methods described below can provide sealing systems for use in isolating reactions in reactors that are in close proximity to other reactors. The reactors isolated according to the sealing systems and methods described herein include single reactors as well as one or more sets or groups of reactors used in one or more of serial, parallel, and/or serial parallel modes.

In some embodiments, the current invention discloses sealing the reactors with improved particle performance and fluid isolation. The seal can include a sharp edged sleeve, for example, a sleeve having conical edges for contacting the substrate to form site isolated regions. The conical sleeve can have a small contact area with a substrate, thus the applied force can be concentrated on a smaller area, e.g., at the tips of the conical edges, to provide greater contact pressure at the sealing interface. Further, the small contact area can reduce the number of generated particles. In addition, when the conical sleeve contacts deformable material, such as a resist layer, a good seal can be obtained by heating the sample before applying the conical sleeve.

In some embodiments, the seal can include a minimal contact sealing surface, such as a majority of the seal can form a small gap with the substrate. The seal can include three or more protrusions (or bumps) pressing on the substrate, leaving a small and consistent gap surrounding the sleeve. A pressure differential can be provided prevent leakage of fluid across the sleeve seal. For example, since there is no continuous wall to exclude chemicals from entering across the sleeve seal, the internal volume of the sleeve can be pressurized by an inert gas. The pressure/flow of the gas can be controlled so that it balances the pressure of the chemistry surrounding the sleeve. Alternatively, the outside ambient can be pressurized to prevent leakage of fluid from the sleeve interior.

“Combinatorial Processing” generally refers to techniques of differentially processing multiple regions of one or more substrates. Combinatorial processing generally varies materials, unit processes or process sequences across multiple regions on a substrate. The varied materials, unit processes, or process sequences can be evaluated (e.g., characterized) to determine whether further evaluation of certain process sequences is warranted or whether a particular solution is suitable for production or high volume manufacturing.

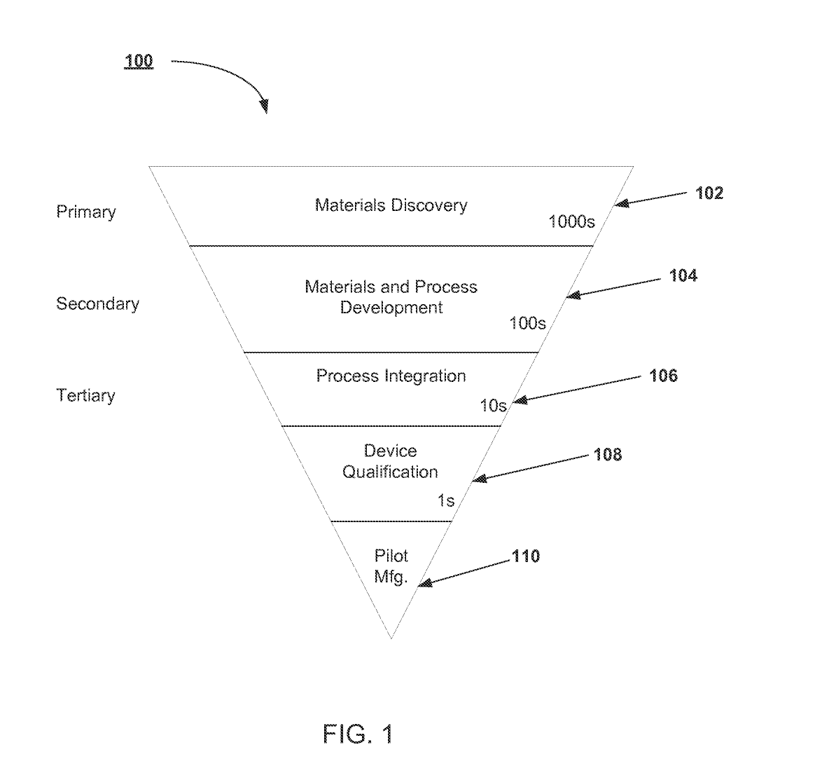

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of IC manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating an IC device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture an IC device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the IC device. For example, such structures may include, but would not be limited to, contact layers, buffer layers, absorber layers, or any other series of layers or unit processes that create an intermediate structure found on IC devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

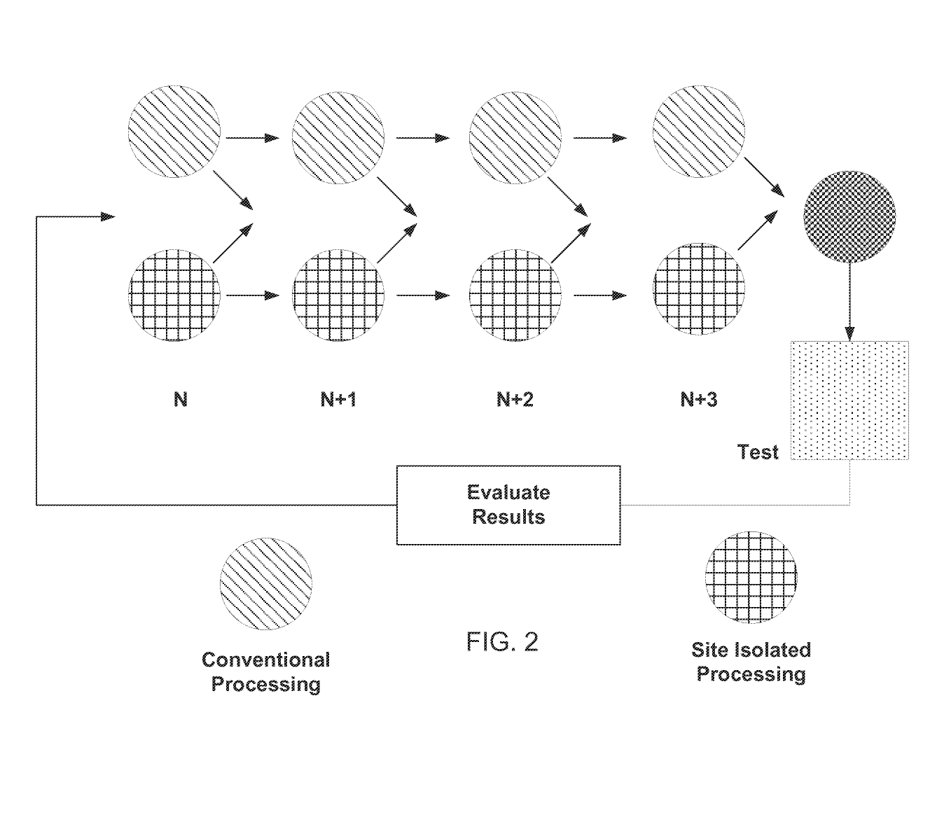

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in IC manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

Combinatorial processing can be used to produce and evaluate different materials, chemicals, processes, process and integration sequences, and techniques related to semiconductor fabrication. For example, combinatorial processing can be used to determine optimal processing parameters (e.g., power, time, reactant flow rates, temperature, etc.) of dry processing techniques such as dry etching (e.g., plasma etching, flux-based etching, reactive ion etching (RIE)) and dry deposition techniques (e.g., physical vapor deposition (PVD), chemical vapor deposition (CVD), atomic layer deposition (ALD), etc.). Combinatorial processing can be used to determine optimal processing parameters (e.g., time, concentration, temperature, stirring rate, etc.) of wet processing techniques such as wet etching, wet cleaning, rinsing, and wet deposition techniques (e.g., electroplating, electroless deposition, chemical bath deposition, etc.).

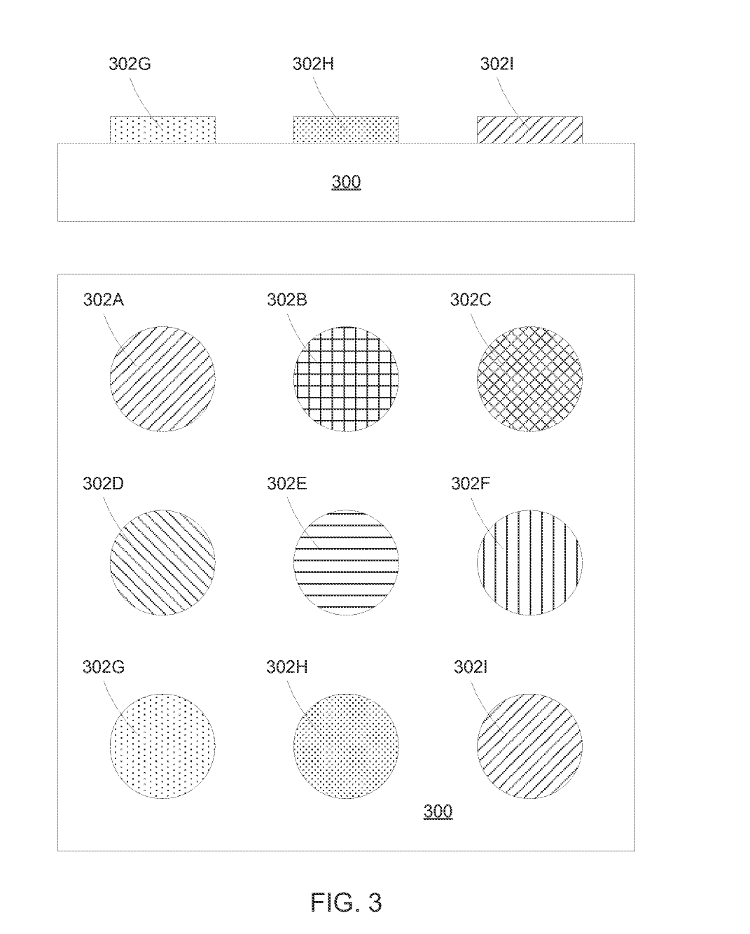

FIG. 3 illustrates a schematic diagram of a substrate that has been processed in a combinatorial manner. A substrate, 300, is shown with nine site isolated regions, 302a-302i, illustrated thereon. Although the substrate 300 is illustrated as being a generally square shape, those skilled in the art will understand that the substrate may be any useful shape such as round, rectangular, etc. The lower portion of FIG. 3 illustrates a top down view while the upper portion of FIG. 3 illustrates a cross-sectional view taken through the three site isolated regions, 302g-302i. The shading of the nine site isolated regions illustrates that the process parameters used to process these regions have been varied in a combinatorial manner. The substrate may then be processed through a next step that may be conventional or may also be a combinatorial step as discussed earlier with respect to FIG. 2.

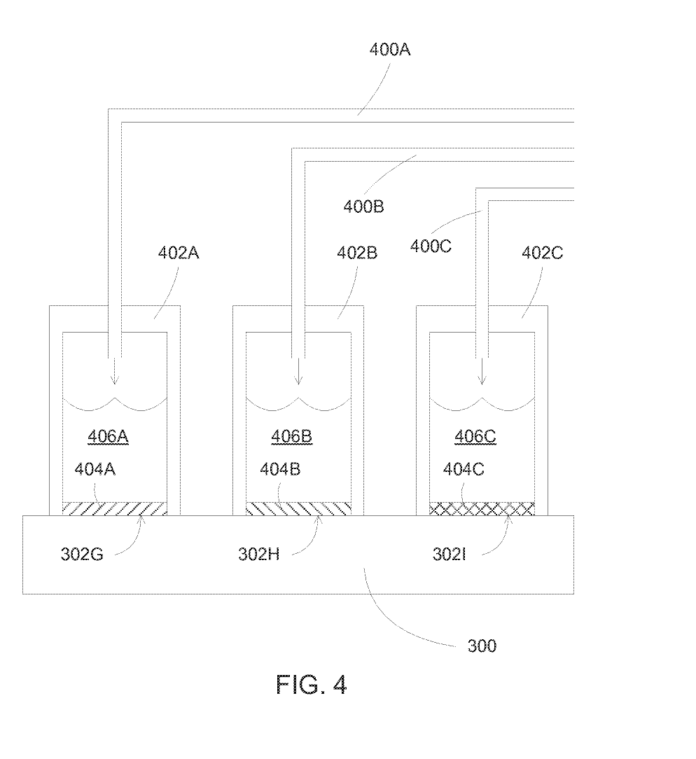

FIG. 4 illustrates a schematic diagram of a combinatorial wet processing system according to an embodiment described herein. A combinatorial wet system may be used to investigate materials deposited by solution-based techniques. An example of a combinatorial wet system is described in U.S. Pat. No. 7,544,574 cited earlier. Those skilled in the art will realize that this is only one possible configuration of a combinatorial wet system. FIG. 4 illustrates a cross-sectional view of substrate, 300, taken through the three site isolated regions, 302g-302i similar to the upper portion of FIG. 3. Solution dispensing nozzles, 400a-400c, supply different solution chemistries, 406a-406c, to chemical processing cells, or reactors, 402a-402c. FIG. 4 illustrates the deposition of a layer, 404a-404c, on respective site isolated regions. Although FIG. 4 illustrates a deposition step, other solution-based processes such as cleaning, etching, surface treatment, surface functionalization, etc. may be investigated in a combinatorial manner. Advantageously, the solution-based treatment can be customized for each of the site isolated regions.

In some embodiments, the present invention discloses systems and methods for generating site isolated regions on a substrate, allowing combinatorial processing without cross contamination between regions. The site isolated regions are sealed against the substrate through a sealing mechanism that can be effective for different substrate surface conditions, including surface layer removal at the sealing interface.

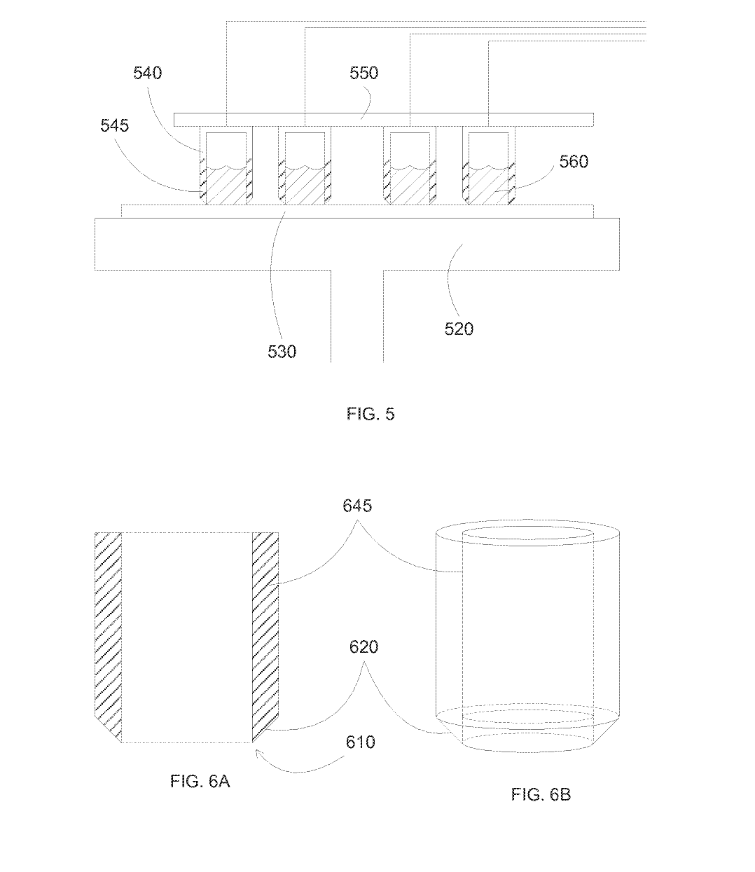

FIG. 5 illustrates an exemplary high productivity combinatorial system, which employs reactor assemblies for creating site isolated regions on a substrate according to some embodiments of the present invention. A chamber, for example, a processing chamber within a high productivity combinatorial system, comprises a substrate support 520. A substrate 530 can be brought to the process chamber, and disposed on the substrate support 520. A plurality of reactors 540, for example, from a reactor assembly 550, is lowered to the substrate surface. A force can be applied to the reactor assembly 550, pushing the reactors 540 against the substrate surface, forming a sealing area at a peripheral of the reactors. The sealing area serves to isolate the inside volume of the reactors from each other and from the outside surrounding area.

Processing fluid 560, such as a processing solution or rinsing water, can be introduced to the reactors for processing the substrate regions isolated by the sealing areas. The fluid is bounded by a seal element, such as a conical seal 545 having sharp edges, to contain the fluid within the reactor volume. The processing of the fluid is then restricted to the isolated regions on the substrate surface inside the reactor areas, with the seal element 545 preventing liquid leakage from under the reactors.

An example of a structure for use in site-isolated processing of unique regions on a substrate includes the use of seals between reactors of the array and one or more regions of a target substrate. In some embodiments, the sealing systems and methods of sealing comprise one or more contact seals, using seals at the interface of the reactors and the substrate surface to enable effective containment of isolated reactions of reactors of an array. The reactors isolated according to the sealing systems and methods described herein include single reactors as well as one or more sets or groups of reactors used in one or more of serial, parallel, and/or serial parallel modes.

FIGS. 6A-6B show a cross section and a perspective view of a conical sealing system according to some embodiments of the present invention. The conical sealing 645 is used in a multiprocessing cell array in order to provide multiple site-isolated reactors 540 for combinatorial processing of portions of the substrate 530 as described above. In some embodiments, the conical sealing conical 645 comprises a cone shape 620 at the lower portion of the seal 635, having sharp edges 610 to minimize the contact area with the substrate. In some embodiments, the sharp edges comprise an angle between 20 and 70 degrees, and preferably between 40 and 50 degrees from the normal direction (e.g., perpendicular) of the substrate surface.

In some embodiments, the sealing mechanism comprises a thin sharp edge ring for pressing on the substrate surface with small contact area. For example, the sealing mechanism can comprise a conical seal having taper edges toward the substrate surface. The small sealing area can concentrate the sealing force, generating higher contact pressure to guard against fluid leakage across the sealing surface, for example, eliminating fluid wicking at the seal interface through capillary action. The conical seal 645 thus provides site-isolated reactors with small contact area, enabling higher contact pressure and lower particle contamination. Effective seals can therefore be achieved on the target substrate because the conical seal can ensure that no leakage of reactants takes place from the reactors.

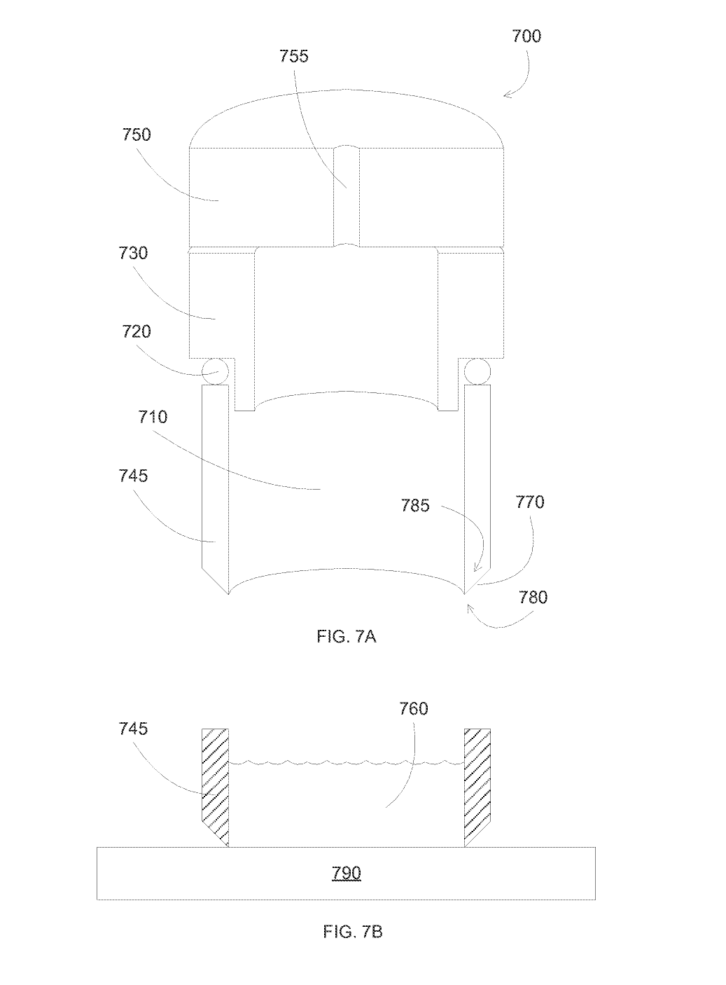

FIG. 7A illustrates an exemplary reactor having a conical seal according to some embodiments of the present invention. A reactor 700 comprises a facility portion 750 for connecting to facility supplies, such as liquid delivery system and an exchangeable reactor head portion 730 to enable swapping reactor heads without disturbing the facility connections. The facility portion can comprise liquid line 755 to provide processing liquid to the reactor volume 710. The head portion 730 is coupled to the facility portion, enabling ease of changing reactors in the combinatorial system.

In some embodiments, the reactor head 730 can comprise a reactor sleeve 745, defining a reactor reaction region 710 within the sleeve 745. In some embodiments, the sleeve 745 is coupled to an upper portion of the reactor head through an o-ring 720, controlling a floating of the sleeve 745 in the reactor 700 over a pre-specified range of motion. The range of motion of an embodiment is therefore determined by dimensions and/or properties of material of the compliance o-ring 720. The floating sleeve 745 and consequently the reactor 700 are shown to be circular but may take on a number of different shapes in other embodiments as appropriate to a processing system.

Therefore, the floating sleeve 745 can float within the reactor 700 so that the seal portion 770 of the sleeve contacts a surface of the substrate. Once the floating sleeve 745 is positioned relative to the substrate surface, the floating sleeve will flex so that an upper portion of the floating sleeve comes into firm contact with a portion of the reactor block so as to maintain the position of the floating sleeve in the reactor block during such time as a reaction is taking place in the reactor.

In some embodiments, the sleeve 745 comprises a seal portion having a conical shape 770 at the sealing surface 780, which presents a sharp edge contact to the substrate. The angle 785 of the sharp edge is less than 90 degrees, and preferably less than about 70 degrees. For stability purposes, the angle of the sharp edge can be greater than about 20 degrees, and preferably greater than about 30 degrees. In some embodiments, the sharp edge can be rounded, for example, to prevent flexing of the sharp tip which can generate particles.

In some embodiments, the sleeve 745 comprises an inert semi-compliant material such as fluoropolymer, which is a fluorocarbon based polymer with multiple strong carbon-fluorine bonds, characterized by a high resistance to solvents, acids, and bases. Examples of fluoropolymers include polychlorotrifluoroethylene (PCTFE), polyethylenechlorotrifluoroethylene (ECTFE), polytetrafluoroethylene (PTFE), perfluoroalkoxy polymer (PFA), polyethylenetetrafluoroethylene (ETFE), and fluorinated ethylene-propylene (FEP).

The contact sealing systems described above are provided as examples of integration into a site-isolated reactor of one or more of the floating sleeve, conical shape having sharp edges of the sealing surface, inert semi-compliant material of the floating sleeve configured to provide a seal of the reactor. Reactors of various alternative embodiments can include configuration variations, such as spring loaded sleeve instead of o-ring, solid construction of reactor head instead of the modular configuration of facility portion and reactor head portion. In addition, the drawings illustrate a conical sleeve with the sharp edges pointing inward, but the invention is not so limited, and any sleeve having sharp edges are within the scope of the present invention, for example, conical sleeve with sharp edge pointing outside, or sleeve with sharp edges in the middle of the sleeve wall.

FIG. 7B illustrates an exemplary configuration of forming a site isolated region according to some embodiments of the present invention. The reactor 700 is brought to a substrate 790 so that the conical sleeve 745 forms contact with the substrate surface. The sharp edge 780 can concentrate the pressing force to the small contact area, forming a good seal between the sleeve 745 and the substrate 790, and preventing leakage of liquid 760 to the outside area. The reaction caused by the liquid 760 is then confined only to the inner region of the sleeve, enabling site isolated regions without cross contamination. The sharp edge 780 can also enable a smaller pressing force on the reactor assembly and still provide acceptable sealing. In addition, the sharp edge can prevent movements of the sleeve, reducing particle generation.

In some embodiments, the present conical seal can be used in a high productivity combinatorial (HPC) system. During normal operation of an HPC system, a reactor module comprising a plurality of reactors can create a plurality of isolated regions on a substrate surface. The isolated regions are processed with process conditions, device structure or materials varying in a combinatorial manner. In an exemplary configuration, a reactor comprises a conical seal, pressing on a region of the substrate surface to create an isolated processing region. The conical seal can improve the pressing contact characteristics, forming better seal due to the conical sharp edges, reducing fluid leakage due to higher contact pressure and reducing particles due to smaller contact area.

In some embodiments, the present invention discloses methods to operate an HPC system comprising reactors having conical seal. Photoresist stripping, layer etching, and depositing can be effectively confined to the site isolated regions with the conical seal.

In some embodiments, the conical seal can form a good seal with a deformable substrate layer, such as a photoresist layer, by heating the deformable layer before forming the seal contact. When cooling, the conical seal can be partially embedded in the deformable layer, improving the sealing characteristics.

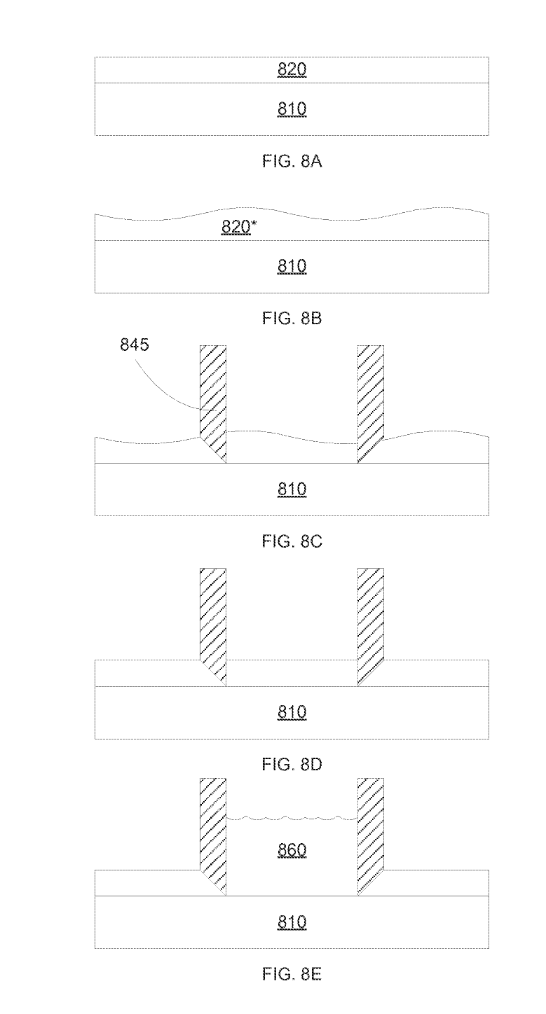

FIGS. 8A-8E illustrate an exemplary process flow for processing a photoresist layer according to some embodiments of the present invention. In FIG. 8A, a photoresist layer 820 is formed on a substrate 810. In FIG. 8B, the substrate is heated to soften the photoresist layer, forming a soft photoresist layer 820*. In FIG. 8C, a reactor is pressed against the photoresist layer 820*, with the conical sleeve 845 penetrating the soft photoresist 820*. In FIG. 8D, the heated photoresist layer 820* is cooled. In FIG. 8E, a processing liquid 860 is introduced to the reactor volume to process the site isolated region defined by the conical sleeve 845. For example, the processing liquid can be a photoresist stripping chemical, dissolving the photoresist within the isolated region.

With the heating action to soften the photoresist layer, the conical sleeve can penetrate the photoresist layer, stopping on the substrate surface. The contact of the sleeve with the substrate surface can form a good seal for the isolated region, even in the event that the photoresist is removed during the subsequent process. In addition, the conical sleeve can form good seal on the photoresist layer, preventing potential wicking of liquid to the outside region by capillary action.

The above description describes an exemplary embodiment for processing photoresist layer, but the present invention is not so limited, and can be applied to any deformable layer or soft layer, such as organic layers, polymer layers or low-k layers. In some embodiments, the layer heating comprises a temperature to soften the layer, for example, to about two third of the melting point, or to about the glass transition temperature. In some embodiments, the heating temperature is less than about 200° C., and preferably less than about 100° C.

In some embodiments, the conical seal can form a good seal with a substrate layer during the removal of the layer within the reaction region.

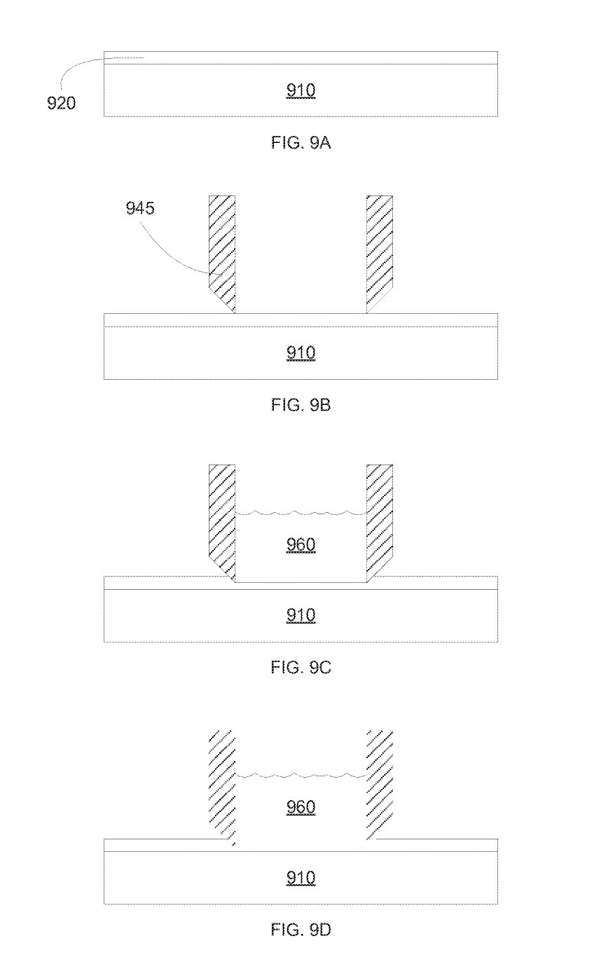

FIGS. 9A-9D illustrate a process flow for processing a layer according to some embodiments of the present invention. In FIG. 9A, a layer 920, such as a silicon oxide layer, is formed on a substrate 910. In FIG. 9B, a reactor is pressed against the layer 920, with the conical sleeve 945 resting on the layer. In FIG. 9C, a processing liquid 960 is introduced to the reactor volume to process the site isolated region defined by the conical sleeve 945. For example, the processing liquid can be an acid, etching the silicon oxide layer within the isolated region. The conical sleeve 945 can be effective in processing the region within the reactor, without liquid leaking and cross contamination.

FIGS. 9C and 9D show a possible mechanism of the sealing process. After a portion of the layer 920 is etched away, the sharp edge of the conical sleeve can move downward due to the pressing force, and thus still forming good sealing contact for the reaction region. Without being bounded by theory, the present sharp edge sleeve can form a good contact seal on a layer during the process of etching the portion of the layer in the reactor region.

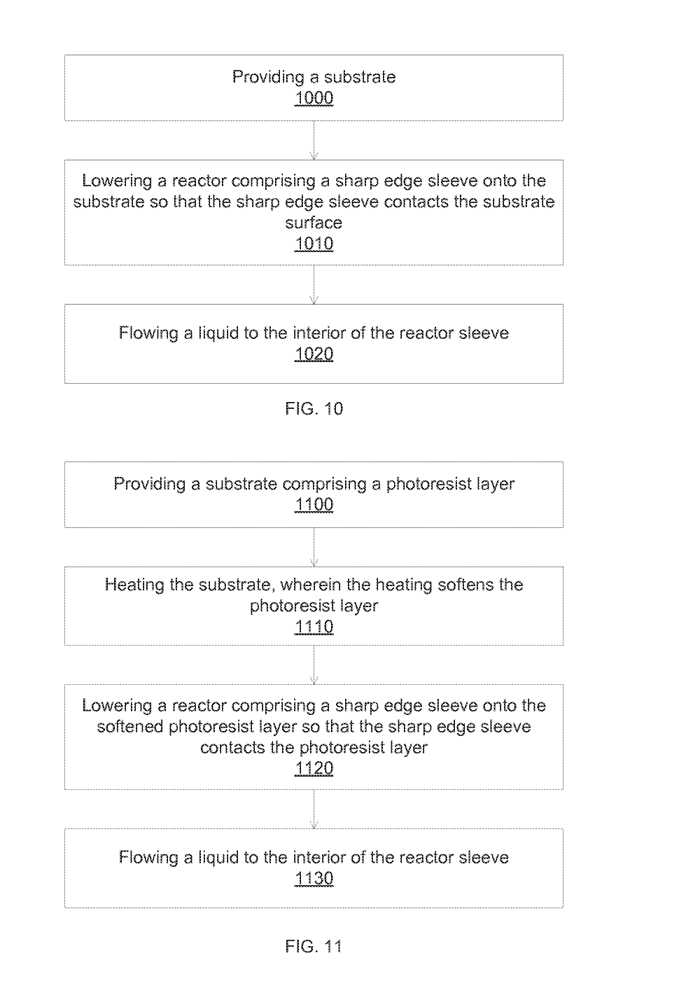

FIG. 10 illustrates a flowchart for forming a site isolated region according to some embodiments of the present invention. In operation 1000, a substrate is provided. In operation 1010, a reactor comprising a sharp edge sleeve is lowered onto the substrate so that the sharp edge sleeve contacts the substrate surface. In operation 1020, a liquid is introduced to the interior of the reactor sleeve.

FIG. 11 illustrates a flowchart for processing a photoresist layer according to some embodiments of the present invention. In operation 1100, a substrate comprising a photoresist layer is provided. In operation 1110, the substrate is heated, which softens the photoresist layer. In some embodiments, the substrate is heated in a heated support, and then the substrate is transferred to a non-heated support. In operation 1120, a reactor comprising a sharp edge sleeve is lowered onto the softened photoresist layer so that the sharp edge sleeve contacts the photoresist layer. In some embodiments, the sharp edge of the sleeve penetrates through the soften photoresist to stop on the substrate surface. In some embodiments, the photoresist is cooled, for example, by stopping the heating if the substrate is disposed on the heated support. In some embodiments, the photoresist is cooled by waiting a certain period, for example, if the substrate is already transferred to a non-heated support. In operation 1130, a liquid is introduced to the interior of the reactor sleeve.

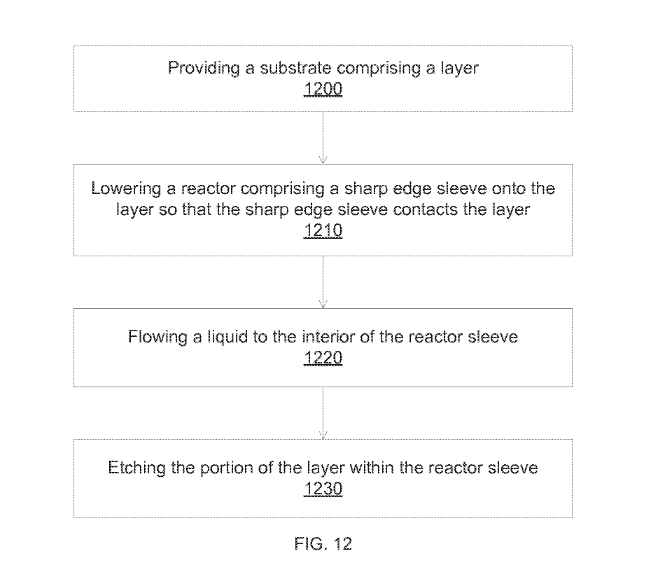

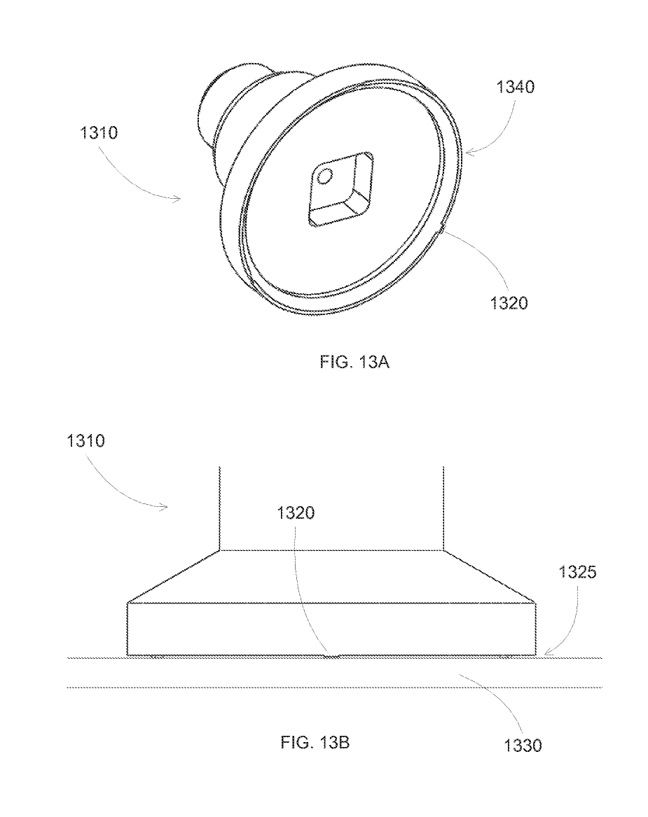

FIG. 12 illustrates a flowchart for processing a layer according to some embodiments of the present invention. In operation 1200, a substrate comprising a layer is provided. In operation 1210, a reactor comprising a sharp edge sleeve is lowered onto the layer so that the sharp edge sleeve contacts the layer. In operation 1220, a liquid is introduced to the interior of the reactor sleeve. In operation 1230, the portion of the layer within the reactor sleeve is etched.

In some embodiments, the current invention discloses a reactor for sealing with a substrate with minimal contacts. The small contact surface of the seal can reduce the amount of particles that are left on a substrate after performing a processing using site isolated regions.

In some embodiments, the seal forms a gap with the substrate, with three or more contacting points. A pressure differential can be applied to prevent fluid leakage across the seal. For example, the internal volume of the reactor can be pressurized by an inert gas, which can balance the pressure of the chemistry surrounding the cup. Alternatively, the internal volume can have a greater pressure than the surrounding ambient to induce a small amount of flow (e.g., bubbles).

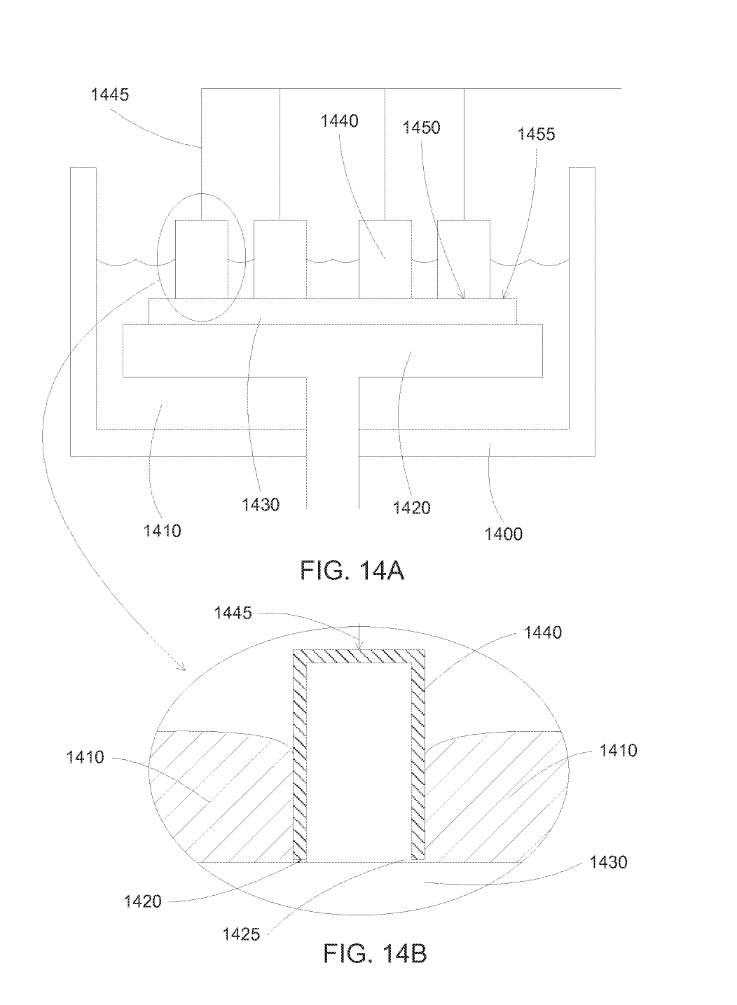

FIGS. 13A-13B illustrate an example of a reactor having contact points according to some embodiments of the current invention. A reactor 1310 can include a number of protrusions 1320 distributed around a periphery of the reactor sealing surface 1340. The protrusions 1320 can form contact points with a substrate 1330, leaving a gap 1325 between the sealing surface 1340 and the surface of the substrate 1330. Smaller contacting surface between the reactor 1310 and the substrate 1330 can be achieved, for example, the contact points can be limited to the protrusions 1320.

In some embodiments, the site isolated regions are the areas of interest in a combinatorial process, since they provide the variations of process and material parameters, which can be evaluated to obtain the optimum device structures and fabrication processes. In some embodiments, the surface areas outside the isolated regions are also processed, such as, to clean or etch the outside surface area. For example, to clean the outside surface areas with a wet cleaning fluid, the isolated regions are protected and cleaning chemical is introduced to the substrate surface.

FIGS. 14A-14B illustrate an example of an outside surface processing according to some embodiments of the present invention. In FIG. 14A, a process chamber 1400 supports a chuck 1420 having a substrate 1430 disposed thereon. The substrate 1430 is submerged in a processing fluid 1410, for example, a cleaning fluid, a rinsing fluid, or an etching fluid. The process chamber 1400 can be a part of a HPC system, which comprises a plurality of protective reactors 1440 protecting isolated regions 1450 of the substrate. Gas lines 1445 can be supplied to the protective chucks 1440, for example, to pressurize the inside of the protective reactors 1440 against the surrounding fluid 1410. The surface area 1455 of the substrate, outside the protected isolated regions 1450, is processed by the processing fluid 1410.

FIG. 14B shows an example of a configuration of a protective reactor 1440 protecting surface 1450 regions of the substrate 1430 against the fluid processing 1410. The protective reactor 1440 can include protrusions 1420, which can contact the substrate 1430 when the protective reactor 1440 is pressed against the substrate, forming a seal with the substrate. The seal can include a gap 1425, which can minimize contact surface with the substrate. Gas flow 1445 can establish a positive pressure within the reactor 1440, which can prevent the fluid 1410 from entering the surface region 1450. The fluid 1410 thus stays within the surface region 1455, outside the region 1450.

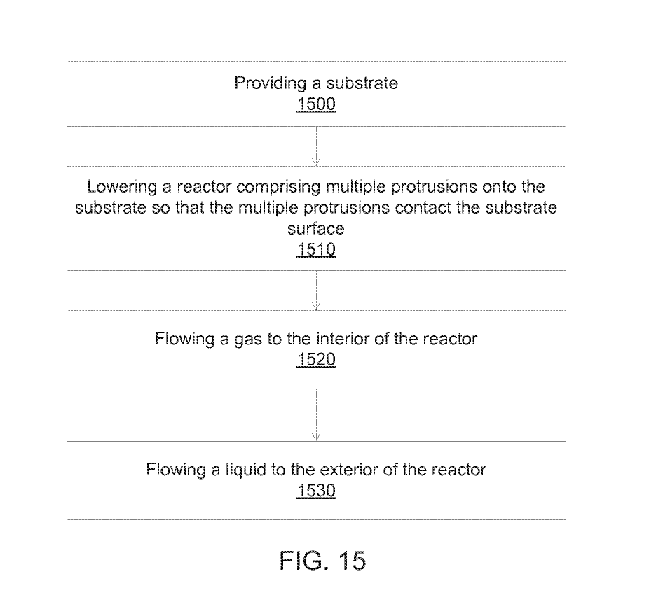

FIG. 15 illustrates a flowchart for forming a site isolated region according to some embodiments of the present invention. In operation 1500, a substrate is provided. In operation 1510, a reactor comprising multiple protrusions is lowered onto the substrate so that the multiple protrusions contact the substrate surface. A site isolated region can be formed on the substrate, including the substrate area within the reactor enclosure. In operation 1520, a gas flows to the interior of the reactor. The gas flow can establish a positive pressure within the reactor, preventing any liquid from entering the site isolated region defined by the reactor. In operation 1530, a liquid is introduced to the exterior of the reactor. The liquid can process the substrate surface, excluding the site isolated region defined by the reactor.

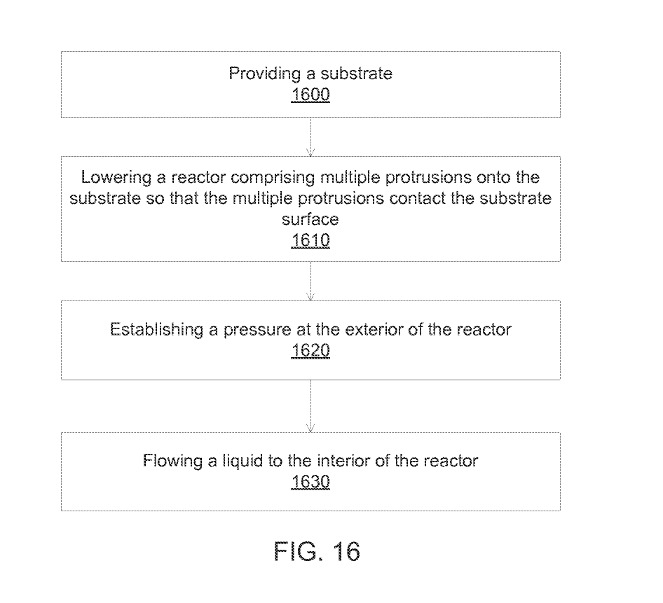

FIG. 16 illustrates another flowchart for forming a site isolated region according to some embodiments of the present invention. In operation 1600, a substrate is provided. In operation 1610, a reactor comprising multiple protrusions is lowered onto the substrate so that the multiple protrusions contact the substrate surface. A site isolated region can be formed on the substrate, including the substrate area within the reactor enclosure. In operation 1620, a pressure is established at the exterior of the reactor. For example, the reactor can be disposed within a sealed chamber, and a gas can flow to the chamber to form a positive pressure with respect to the volume within the reactor. The positive pressure can prevent any liquid from leaking outside of the site isolated region defined by the reactor. In operation 1630, a liquid is introduced to the interior of the reactor. The liquid can process the site isolated region defined by the reactor.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A method for processing a substrate, the method comprising
providing a substrate, wherein the substrate comprises a photoresist layer disposed on the surface of the substrate;
heating the substrate;
contacting the heated photoresist layer with a reactor, wherein the reactor comprises a sharp edge for contacting the substrate surface, wherein the contacting forms a site isolated region on the substrate surface.

2. A method as in claim 1 wherein the sharp edge comprises a conical surface.

3. A method as in claim 1 wherein the reactor comprises a sleeve coupled to a reactor body, and wherein the sleeve comprises a sharp edge for contacting the substrate surface.

4. A method as in claim 1 wherein the reactor comprises a sleeve coupled to a reactor body, and wherein the sleeve comprises a conical surface.

5. A method as in claim 1 further comprising
applying a force to press the sharp edge against the substrate surface.

6. A method as in claim 1 wherein the sharp edge penetrates through the photoresist layer to contact the substrate surface.

7. A method as in claim 1 further comprising
introducing a fluid on the site isolated region.

8. A method as in claim 7 wherein the fluid etches the portion of the photoresist layer within the site isolated region.

9. A method for processing a substrate in a high productivity combinatorial equipment, the method comprising
providing a substrate, wherein the substrate comprises a layer disposed on the surface of the substrate;
contacting the layer with a reactor, wherein the reactor comprises a sharp edge for contacting the layer surface, wherein the contacting forms a site isolated region on the substrate surface;
introducing a fluid to the interior of the reactor;
etching a portion of the layer in the site isolated region.

10. A method as in claim 9 wherein the sharp edge comprises a conical surface.

11. A method as in claim 9 wherein the reactor comprises a sleeve coupled to a reactor body, and wherein the sleeve comprises a sharp edge for contacting the substrate surface.

12. A method as in claim 9 wherein the reactor comprises a sleeve coupled to a reactor body, and wherein the sleeve comprises a conical surface.

13. A method as in claim 9 further comprising applying a force to press the sharp edge against the substrate surface.

14. A method as in claim 9 wherein the sharp edge is further lowered to contact the expose surface of the layer after a portion of the layer is etched away.

15. A method as in claim 9 wherein the sharp edge forms a seal with the substrate surface to prevent leakage of fluid across the sealing surface after a portion of the layer is removed.

16. A high productivity combinatorial processing module, comprising:
a plurality of reaction chambers;
a sleeve coupled to each of the reaction chambers, wherein the sleeve comprises a sharp edge for forming a site isolated region on a substrate.

17. A module as in claim 16, further comprising
a liquid inlet coupled to each of the reaction chambers, wherein the liquid inlet is configured to deliver a liquid material to an interior of the reaction chamber.

18. A module as in claim 16, further comprising
a gas inlet coupled to each of the reaction chambers, wherein the gas inlet is configured to deliver a gaseous material to an interior of the reaction chamber.

19. A module as in claim 16 wherein the sharp edge comprises a conical surface.

20. A module as in claim 16, further comprising
a mechanism for applying a force to press the sharp edge against the substrate surface.
